(19) United States
(12) Patent Application Publication
(10) Pub. No.: US 2016/0282460 A1
(43) Pub. Date: Sep. 29, 2016

(54) OBJECT RECOGNITION APPARATUS AND OBJECT RECOGNITION METHOD USING SPATIAL ELECTROMAGNETIC WAVES

(71) Applicant: Electronics and Telecommunications Research Institute, Daejeon-si (KR)

(72) Inventors: Jin Woo HONG, Daejeon-si (KR); Jong Soo LIM, Daejeon-si (KR)

(73) Assignee: Electronics and Telecommunications Research Institute, Daejeon-si (KR)

(21) Appl. No.: 15/081,047

(22) Filed: Mar. 25, 2016

(30) Foreign Application Priority Data
Mar. 26, 2015 (KR) 10-2015-0042729

(51) Int. Cl. G01S 13/56; G01S 13/04; G01R 29/08

(52) U.S. Cl. CPC G01S 13/56; G01R 29/0878; G01S 13/04

(57) ABSTRACT

Disclosed is an object recognition apparatus using spatial electromagnetic waves. The object recognition apparatus includes: a spatial electromagnetic wave measurer configured to measure a signal strength of electromagnetic waves generated for a predetermined purpose in a specific space; and an object recognizer configured to recognize an object present in the specific space based on whether there is a change in the measured signal strength.

### CROSS-REFERENCE TO RELATED APPLICATION(S)

This application claims priority from Korean Patent Application No. 10-2015-0042729, filed on Mar. 26, 2015, in the Korean Intellectual Property Office, the entire disclosures of which are incorporated herein by references for all purposes.

### BACKGROUND

1. Field

The following description generally relates to an object recognition apparatus and an object recognition method, and more particularly to an object recognition apparatus and method using various types of electromagnetic waves present in a space.

2. Description of the Related Art

A general object recognition technology recognizes objects by detecting a change in a source signal (light, electromagnetic waves, etc.) which is transmitted by a transmitter installed in a space and is reflected by a receiver. Accordingly, the general object recognition technology essentially includes a pair of a transmitter to transmit a source signal and a receiver to receive the source signal.

However, such general object recognition apparatus has a drawback in that its installation is inefficient since a pair of a transmitter and a receiver should be included. That is, the installation position of a receiver is dependent on the installation position of a transmitter, such that the receiver is required to be installed at a specific position, and both the transmitter and the receiver are required such that an installation cost is increased. Further, when there is a failure in the transmitter, relevant services may not be provided.

### SUMMARY

The present disclosure provides an object recognition apparatus and method using spatial electromagnetic waves, in which the presence or change of objects may be detected and identified by using only a receiver without any need to install a transmitter in a space.

In one general aspect, there is provided an object recognition apparatus using spatial electromagnetic waves, the apparatus including: a spatial electromagnetic wave measurer configured to measure a signal strength of electromagnetic waves generated for a predetermined purpose in a specific space; and an object recognizer configured to recognize an object present in the specific space based on whether there is a change in the measured signal strength.

In another general aspect, there is provided an object recognition method using spatial electromagnetic waves, the method including: measuring a signal strength of electromagnetic waves generated for a predetermined purpose in a specific space; and based on whether there is a change in the measured signal strength, recognizing an object present in the specific space.

### BRIEF DESCRIPTION OF THE DRAWINGS

FIG. 1 is a block diagram illustrating an object recognition apparatus using spatial electromagnetic waves according to an exemplary embodiment.

FIGS. 2A and 2B are diagrams explaining how an object recognition apparatus using spatial electromagnetic waves operates according to an exemplary embodiment.

FIG. 3 is a block diagram illustrating a spatial electromagnetic wave measurer according to an exemplary embodiment.

FIG. 4 is a block diagram illustrating an object recognizer according to an exemplary embodiment.

FIG. 5 is a flowchart explaining an object recognition method using spatial electromagnetic waves according to an exemplary embodiment.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, exemplary embodiments of the present disclosure will be described in detail with reference to the accompanying drawings to help those skilled in the art to easily understand and carry out the present invention.

In the following description, a detailed description of known functions and configurations incorporated herein will be omitted when it may obscure the subject matter of the present invention.

Further, the terms used throughout this specification are defined in consideration of the functions in exemplary embodiments, and can be varied according to a purpose of a user or manager, or precedent and so on. Therefore, definitions of the terms should be made on the basis of the overall context.

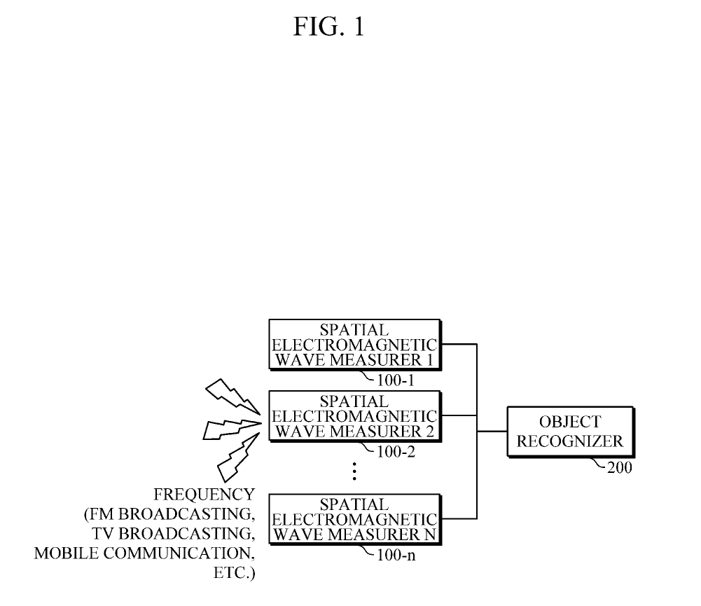

FIG. 1 is a block diagram illustrating an object recognition apparatus using spatial electromagnetic waves according to an exemplary embodiment.

Referring to FIG. 1, the object recognition apparatus using spatial electromagnetic waves includes spatial electromagnetic wave measurers 100-1, 100-2, . . . , and 100-n, and an object recognizer 200.

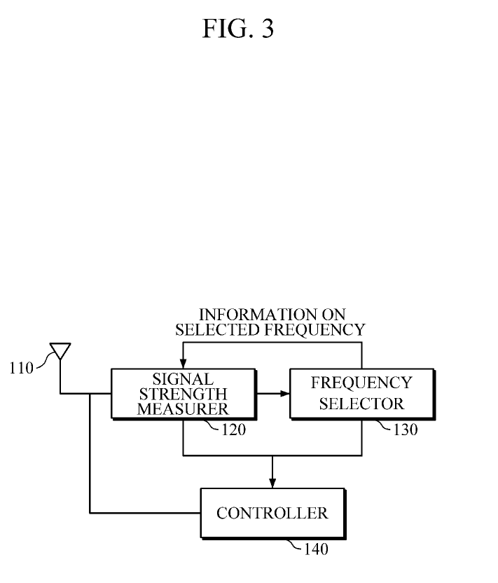

The spatial electromagnetic wave measurers 100-1, 100-2, . . . , and 100-n measure a signal strength of electromagnetic waves generated for a predetermined purpose in a space. The electromagnetic waves may be one type of electromagnetic waves, or two or more types of electromagnetic waves having different frequencies, which are present in a space. For example, the electromagnetic waves may be a wireless electromagnetic wave signal in a space to provide services of a specific purpose, such as FM broadcasting, TV broadcasting, mobile communications, and the like. In one exemplary embodiment, two or more spatial electromagnetic wave measurers 100-1, 100-2, . . . , and 100-n may be located at different positions, as illustrated in FIG. 1. Further, in another exemplary embodiment, in the case where there is one spatial electromagnetic wave measurer, the spatial electromagnetic wave measurer may serve as the object recognizer 200. The spatial electromagnetic wave measurers 100-1, 100-2, . . . , and 100-n will be described in detail later with reference to FIG. 3.

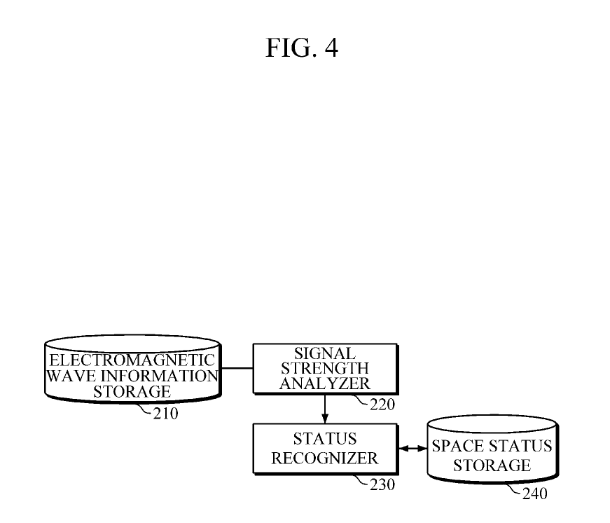

Depending on whether there is a change in the strength of signals measured by one or more spatial electromagnetic wave measurers 100-1, 100-2, . . . , and 100-n, the object recognizer 200 recognizes an object located in a specific space. The object recognizer 200 will be described in detail later with reference to FIG. 4.

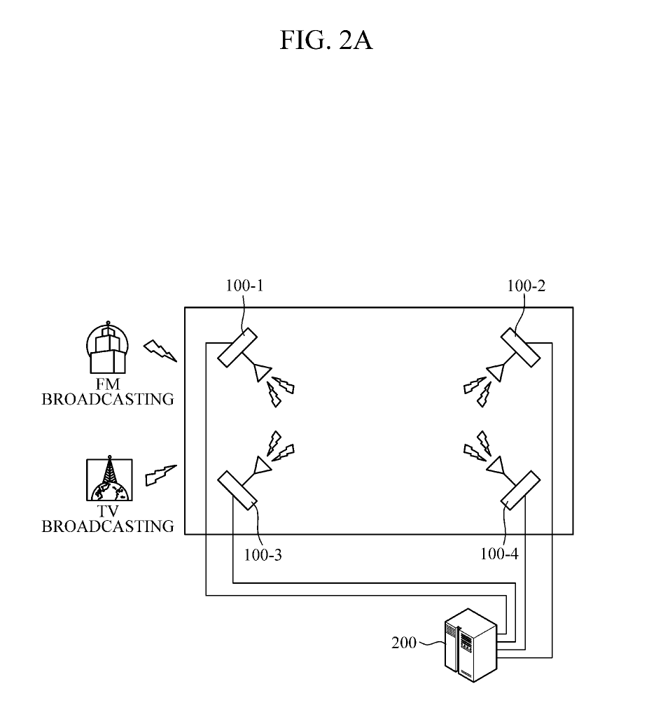

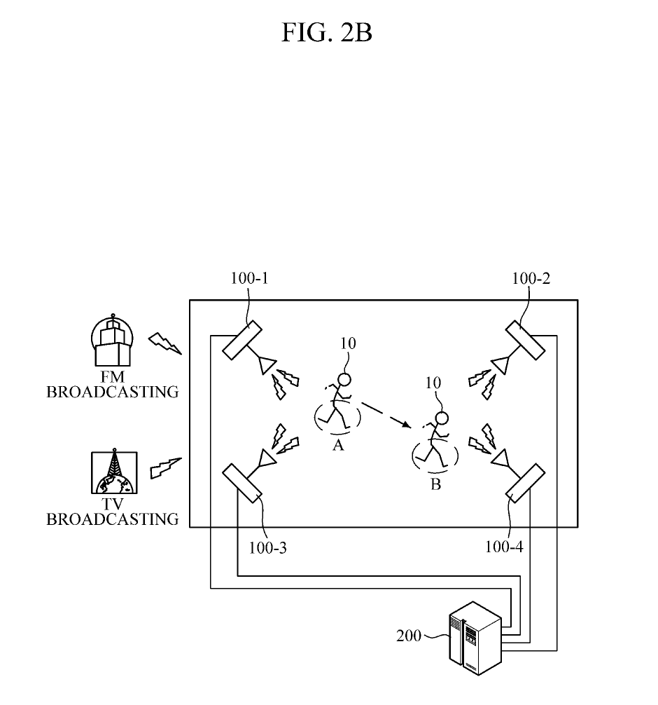

FIGS. 2A and 2B are diagrams explaining how an object recognition apparatus using spatial electromagnetic waves operates according to an exemplary embodiment. For better understanding, it is assumed that electromagnetic waves present in a space are electromagnetic waves only in a FM broadcasting frequency band and a TV broadcasting frequency band. However, it is merely an exemplary embodiment, and the present disclosure is not limited thereto. That is, there may be electromagnetic waves in either the FM broadcasting frequency band or the TV broadcasting frequency band, or there may be another type of electromagnetic waves.

Referring to FIG. 2A, the spatial electromagnetic wave measurers 100-1, 100-2, . . . , and 100-n may measure a signal strength in the FM broadcasting frequency band and the TV broadcasting frequency band, and may select a frequency having a higher signal strength than the other. In the embodiment, the FM broadcasting frequency band is selected as a frequency band range, but a full band may also be selected.

The object recognizer 200 recognizes an object change by using the signal strength transmitted from the spatial electromagnetic wave measurers 100-1, 100-2, . . . , and 100-n. In the case where there is only one type of electromagnetic waves (for example, electromagnetic waves in only the FM broadcasting frequency band or the TV broadcasting frequency band), the object recognizer 200 may recognize an object change based on a signal strength of one type of existing electromagnetic waves without selecting a frequency of electromagnetic waves.

Referring to FIG. 2B, the FM broadcasting frequency measured by each of the spatial electromagnetic wave measurers 100-1, 100-2, . . . , and 100-n is reflected from an object 10 in a space or is interrupted by the object 10, such that a signal strength is changed to be different from a signal strength in an environment of FIG. 2A. Upon identifying such change, the object recognizer 200 determines that the object 10 is recognized. Further, in the case where the object 10 moves from area A to area B, the object recognizer 200 may recognize a location change of the object according to the change in the frequency signal strength measured by the spatial electromagnetic wave measurers 100-1, 100-2, . . . , and 100-n, and may determine locations of area A and area B.

FIG. 3 is a block diagram illustrating a spatial electromagnetic wave measurer according to an exemplary embodiment.

Referring to FIG. 3, each of the spatial electromagnetic wave measurers 100-1, 100-2, . . . , and 100-n includes an antenna 110, a signal strength measurer 120, a frequency selector 130, and a controller 140.

The antenna 110 may receive electromagnetic waves generated for a predetermined purpose in a space. The signal strength measurer 120 may measure a signal strength of electromagnetic waves in two or more different frequency bands which are received by the antenna 110 and are generated in a specific space.

The frequency selector 130 may monitor the signal strength of electromagnetic waves in two or more different frequency bands that are measured by the signal strength measurer 120 and are generated in a specific space, and may select a predetermined number of electromagnetic waves according to the monitored signal strength. Further, the frequency selector 130 may control the signal strength measurer 120 to measure a signal strength of the selected electromagnetic waves. For example, when a user is absent from home, the frequency selector 130 automatically selects a frequency having the highest signal efficiency from among the FM broadcasting frequency, the TV broadcasting frequency, the mobile communication frequency, and the like, so that a signal strength may be measured in an environment where there is nobody. The signal strength measurer 120 may be configured to measure a signal strength at a predetermined interval.

The controller 140 may manage the measured signal strength, or may transmit the measured signal strength to the object recognizer 200. In another exemplary embodiment, in the case where there is one spatial electromagnetic wave measurer, the controller 140 may serve as the object recognizer 200.

FIG. 4 is a block diagram illustrating an object recognizer according to an exemplary embodiment.

Referring to FIG. 4, the object recognizer 200 includes an electromagnetic wave information storage 210, a signal strength analyzer 220, a status recognizer 230, and a space status storage 240.

The electromagnetic wave information storage 210 may receive the types and signal strength of electromagnetic waves from the spatial electromagnetic wave measurers 100-1, 100-2, . . . , and 100-n, and may store the received types and signal strength of electromagnetic waves, in which the electromagnetic wave information storage 210 may store the types and signal strength of electromagnetic waves along with measurement locations and times.

The signal strength analyzer 220 may determine whether the signal strength measured by each of the spatial electromagnetic wave measurers 100-1, 100-2, . . . , and 100-n is different from a previously measured signal strength, and may notify the status recognizer 230 if there is a change in the signal strength.

In the case where there is a change in the signal strength, the status recognizer 230 recognizes space status that includes the presence or movement of an object. Further, the status recognizer 230 stores the recognized space status in the space status storage 240. Then, the space recognizer 230 may later recognize current space status by reference to previously recognized space status stored in the space status storage 240. For example, in the case where the object 10 moves to the right as illustrated in FIG. 2B, the status recognizer 230 may recognize that the object 10 moves from A to B by referring to the previously recognized space status stored in the space status storage 240 and by recognizing that a signal strength measured by the spatial electromagnetic wave measurer 100-1 is increased, and a signal strength measured by the spatial electromagnetic wave measurer 100-4 is decreased.

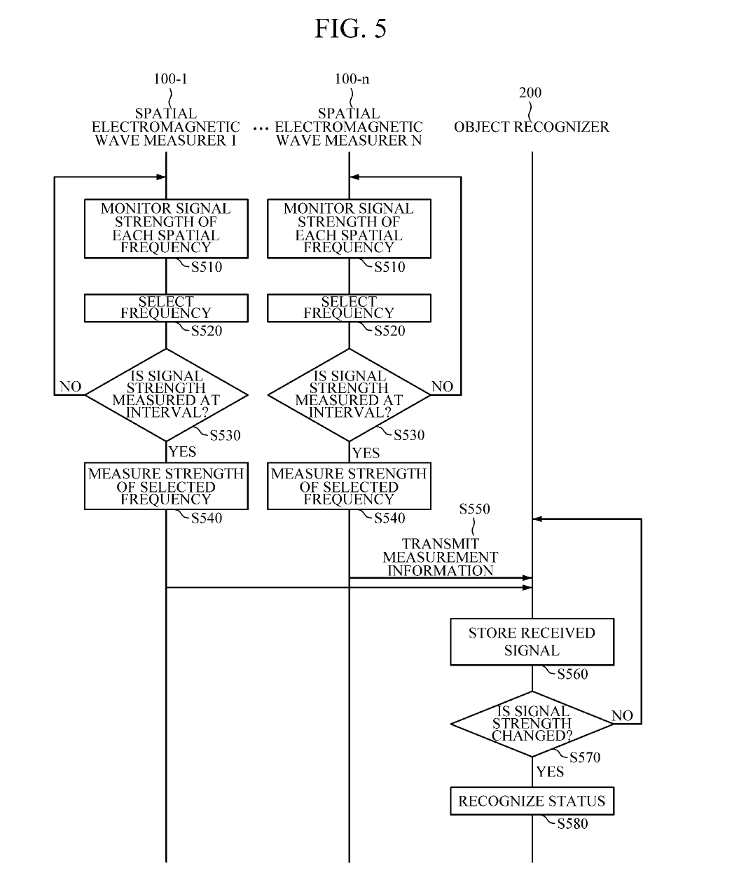

FIG. 5 is a flowchart illustrating an object recognition method using spatial electromagnetic waves according to an exemplary embodiment.

Referring to FIG. 5, each of the spatial electromagnetic wave measurers 100-1, 100-2, . . . , and 100-n measures a signal strength of electromagnetic waves generated in a space in S510 to S540. The spatial electromagnetic wave measurers 100-1, 100-2, . . . , and 100-n may measure the signal strength at two or more different locations. More specifically, the spatial electromagnetic wave measurers 100-1, 100-2, . . . , and 100-n monitor the signal strength of electromagnetic waves in two or more different frequency bands in S510. Then, the spatial electromagnetic wave measurers 100-1, 100-2, . . . , and 100-n select a predetermined number of electromagnetic waves according to the monitored signal strength in S520. When measuring a signal strength of the selected electromagnetic waves in S540, the spatial electromagnetic wave measurers 100-1, 100-2, . . . , and 100-n may measure the signal strength at a predetermined interval in S530. The spatial electromagnetic wave measurers 100-1, 100-2, . . . , and 100-n transmit measurement information to the object recognizer 200 in S550.

Subsequently, based on whether there is a change in the signal strength measured by each of the spatial electromagnetic wave measurers 100-1, 100-2, . . . , and 100-n, the object recognizer 200 recognizes an object present in a specific space in S560 to S580. More specifically, the object recognizer 200 receives the types and signal strength of electromagnetic waves from the spatial electromagnetic wave measurers 100-1, 100-2, . . . , and 100-n, and stores the received types and signal strength in S560. The types and signal strength of electromagnetic waves may be stored along with measurement locations and times.

The object recognizer 200 determines whether the signal strength, measured by each of the spatial electromagnetic wave measurers 100-1, 100-2, . . . , and 100-n, is different from a previously measured signal strength in S570.

Upon determination in S570, if the signal strength is changed, the object recognizer 200 recognizes space status that includes the presence or movement of the object in S580. In this case, the object recognizer 200 may store recognized space status, and may recognize current space status by reference to the recognized space status that has been stored.

In the present disclosure, an object change may be detected and recognized by using only a receiver without any need to install a transmitter in a space, thereby reducing an installation cost, and enabling easy installation of the receiver in a space. Further, the object recognition apparatus and method may be applied to security sensors in the home or offices, or sensors that recognize moving directions of objects in an indoor space, since objects may be detected or movement of objects may be identified with no failure or error occurring in a transmitter. In addition, no transmitter is required, such that an invader may not remove or block the transmitter, as in the case of existing products, thereby ensuring a higher reliability than other existing products. Moreover, a receiver may be installed in a desired space, and a plurality of receivers may also be installed according to precision desired by a user. Unlike the general technology, the present disclosure uses electromagnetic waves generated by a transmitter in a space where the transmitter is located, and thus may be applied to a totally new concept of future technologies.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims. Further, the above-described examples are for illustrative explanation of the present invention, and thus, the present invention is not limited thereto.

What is claimed is:

1. An object recognition method using spatial electromagnetic waves, the method comprising:
measuring a signal strength of electromagnetic waves generated for a predetermined purpose in a specific space; and
based on whether there is a change in the measured signal strength, recognizing an object present in the specific space.

2. The method of claim 1, wherein the measuring comprises:
monitoring the signal strength of electromagnetic waves of one frequency band or two or more different frequency bands that are generated in the specific space;
selecting a predetermined number of electromagnetic waves according to the monitored signal strength; and
measuring the signal strength of the selected electromagnetic waves.

3. The method of claim 1, wherein the measuring comprises measuring the signal strength at two or more different locations.

4. The method of claim 1, wherein the measuring comprises measuring the signal strength at a predetermined interval.

5. The method of claim 1, wherein the recognizing comprises:
storing the measured signal strength;
determining whether the measured signal strength is different from a previously measured signal strength; and
In response to a determination that the measured signal strength is different from the previously measured signal strength, recognizing space status that includes presence or movement of the object.

6. The method of claim 5, wherein the storing comprises storing the measured signal strength along with measurement locations and times.

7. The method of claim 5, wherein in response to generation of electromagnetic waves of two or more different frequency bands, the recognizing comprises determining whether there is a change in the signal strength of each of the electromagnetic waves.

8. The method of claim 6, wherein the recognizing comprises recognizing current space status by reference to previously recognized space status.

9. An object recognition apparatus using spatial electromagnetic waves, the apparatus comprising:
a spatial electromagnetic wave measurer configured to measure a signal strength of electromagnetic waves generated for a predetermined purpose in a specific space; and
an object recognizer configured to recognize an object present in the specific space based on whether there is a change in the measured signal strength.

10. The apparatus of claim 9, wherein the spatial electromagnetic wave measurer comprises:
a frequency selector configured to monitor the signal strength of electromagnetic waves of one frequency band or two or more different frequency bands that are generated in the specific space, and to select a predetermined number of electromagnetic waves according to the monitored signal strength; and
a signal strength measurer configured to measure the signal strength of the selected electromagnetic waves.

11. The apparatus of claim 9, wherein two or more spatial electromagnetic wave measurers are located at different positions.

12. The apparatus of claim 9, wherein the spatial electromagnetic wave measurer measures the signal strength at a predetermined interval.

13. The apparatus of claim 9, wherein the object recognizer comprises:
an electromagnetic wave storage configured to store the measured signal strength;
a signal strength analyzer configured to determine whether the measured signal strength is different from a previously measured signal strength; and
a status recognizer, wherein in response to a determination that the measured signal strength is different from the previously measured signal strength, the status recognizer recognizes space status that includes presence or movement of the object.

14. The apparatus of claim 13, wherein the electromagnetic wave storage stores the measured signal strength along with measurement locations and times.

15. The apparatus of claim 13, wherein in response to generation of electromagnetic waves of two or more different frequency bands, the object recognizer determines whether there is a change in the signal strength of each of the electromagnetic waves.

16. The apparatus of claim 13, wherein:
the object recognizer further comprises a space status storage configured to store the recognized space status; and
the status recognizer recognizes current space status by reference to previously recognized space status.
